(19) United States
(12) Patent Application Publication
(10) Pub. No.: US 2025/0142771 A1
(43) Pub. Date: May 1, 2025

(54) COOLING PLATE AND COOLING SYSTEM

(71) Applicant: NIO Technology (Anhui) Co., Ltd., Hefei (CN)

(72) Inventors: Bradley J. Angier, Santa Cruz, CA (US); Anthony P. Nguyen, San Jose, CA (US); Karl Yngve Johnson, Felton, CA (US); Mehdi Rezaeisaray, San Jose, CA (US)

(73) Assignee: NIO Technology (Anhui) Co., Ltd., Hefei (CN)

(21) Appl. No.: 18/497,670

(22) Filed: Oct. 30, 2023

(51) Int. Cl. H05K 7/20; B60K 11/04

(52) U.S. Cl. CPC H05K 7/20254; B60K 11/04; H05K 7/20509

(57) ABSTRACT

A cooling plate comprises a top layer and a bottom layer attached to the top layer. A fluid passage is formed between the top layer and the bottom layer and has an inlet and an outlet. The inlet forms on a first edge of the cooling plate and the outlet forms on a second edge of the cooling plate. One of the top layer and the bottom layer is flat and the other has a raised portion forming inside a fluid groove which opens to the one of the top layer and the bottom layer and forms the fluid passage when the top layer is attached to the bottom layer. An inlet fitting is partially inserted into the inlet. The inlet fitting and the outlet fitting each is sandwiched between the top layer and the bottom layer and extends substantially in the same plane as the fluid passage.

### TECHNICAL FIELD

The described embodiments relate generally to cooling plates, and more particularly to sheet metal cooling plates.

### BACKGROUND

Liquid cooling plates are integral components of liquid cooling systems designed to manage waste heat generated by electronic components, or any other surfaces with high heat loads. A liquid cooling plate transfers heat from the high heat load surfaces to the liquid circulating within the liquid cooling system. Heat is then transferred into either an ambient or another liquid in a secondary cooling system. The performance of liquid cooling plates can directly influence the overall efficiency and effectiveness of the entire liquid cooling system. Flow geometry that increases flow resistance can increase coolant flow pressure drop, and thereby reducing cooling efficiency or the heat transfer capability of a cooling plate. Conventional liquid cooling plates can have high pressure drop in the cooling flow channels and low cooling efficiency. Additionally, conventional liquid cooling plates can have bulky structures to accommodate the fittings equipped with their inlets and outlets. As such, there is a need for liquid cooling plates that have higher cooling efficiency and more efficient system packaging than conventional liquid cooling plates.

### SUMMARY

According to aspects of the present disclosure, a cooling plate can comprise a top layer and a bottom layer attached to the top layer. A fluid passage can be formed between the top layer and the bottom layer and has an inlet and an outlet, wherein the inlet forms on a first edge of the cooling plate and the outlet forms on a second edge of the cooling plate. One of the top layer and the bottom layer can be flat and the other of the top layer and the bottom layer has a raised portion forming inside a fluid groove, and the fluid groove opens to the one of the top layer and the bottom layer and forms the fluid passage when the top layer and the bottom layer can be attached to each other. An inlet fitting can be partially inserted into the inlet. The inlet fitting can be sandwiched between the top layer and the bottom layer and extends substantially in the same plane as the fluid passage. An outlet fitting can be partially inserted into the outlet. The outlet fitting can be sandwiched between the top layer and the bottom layer and extends substantially in the same plane as the fluid passage.

According to other aspects of the present disclosure, a cooling system can be provided and includes a cooling plate. The cooling plate comprises a top layer and a bottom layer attached to the top layer. A fluid passage can be formed between the top layer and the bottom layer and has an inlet and an outlet, wherein the inlet forms on a first edge of the cooling plate and the outlet forms on a second edge of the cooling plate. One of the top layer and the bottom layer can be flat and the other of the top layer and the bottom layer has a raised portion forming inside a fluid groove, and the fluid groove opens to the one of the top layer and the bottom layer and forms the fluid passage when the top layer and the bottom layer can be attached to each other. An inlet fitting can be partially inserted into the inlet. The inlet fitting can be sandwiched between the top layer and the bottom layer and extends substantially in the same plane as the fluid passage. An outlet fitting can be partially inserted into the outlet. The outlet fitting can be sandwiched between the top layer and the bottom layer and extends substantially in the same plane as the fluid passage.

These and other features of the present disclosure will become readily apparent upon further review of the following specification and drawings.

### BRIEF DESCRIPTION OF THE DRAWINGS

The accompanying drawings, which are incorporated in and constitute a part of this disclosure, illustrate exemplary embodiments and, together with the description, serve to explain the disclosed principles.

FIG. 1 shows a vehicle incorporating one or more example cooling systems in according with embodiments of the present disclosure.

FIG. 2 is a perspective view of an example cooling plate in accordance with embodiments of the present disclosure.

FIG. 3 is an exploded view of the example cooling plate as shown in FIG. 2 in accordance with embodiments of the present disclosure.

FIG. 4 is a sectional view of the cooling plate taken along the line A-A of FIG. 2 in accordance with embodiments of the present disclosure.

FIG. 5 is a sectional view of the cooling plate taken along the line B-B of FIG. 2 in accordance with embodiments of the present disclosure.

FIG. 6 is a sectional view of the inlet and the inlet fitting of the example cooling plate before they are assembled in accordance with embodiments of the present disclosure.

FIG. 7 shows a sectional view of the inlet and the inlet fitting of the example cooling plate after they are assembled in according with embodiments of the present disclosure.

FIG. 8 shows a sectional view of the inlet area of another example cooling plate in accordance with embodiments of the present disclosure.

FIG. 9 shows a perspective view of the inlet area of an example cooling plate in accordance with embodiments of the present disclosure.

FIG. 10 shows a perspective view of an inlet area of another example cooling plate in accordance with embodiments of the present disclosure.

### DETAILED DESCRIPTION

As required, detailed embodiments of the present disclosure are disclosed herein; however, it is to be understood that the disclosed embodiments are merely examples that may be embodied in various and alternative forms. The figures are not necessarily to scale; some features may be exaggerated or minimized to show details of particular components. Therefore, specific structural and functional details disclosed herein are not to interpreted as limiting, but merely as a representative basis for teaching one skilled in the art to variously employ the present disclosure.

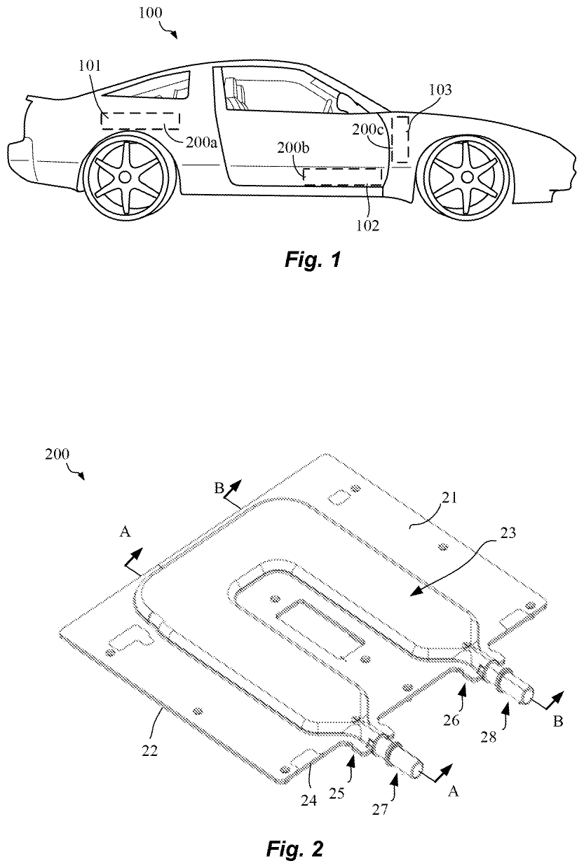

FIG. 1 shows a vehicle 100 incorporating one or more cooling systems 200a, 200b, 200c for cooling one or more electronic components of the vehicle in according with embodiments of the present disclosure. As shown in FIG. 1, the vehicle 100 may include any conveyance or model of a conveyance, where the conveyance was designed for the purpose of moving one or more tangible objects, such as people, animals, cargo, and the like. The term “vehicle” does not require that a conveyance moves or is capable of movement. Typical vehicles may include but are in no way limited to electric vehicles, cars, trucks, motorcycles, busses, automobiles, trains, railed conveyances, boats, ships, marine conveyances, submarine conveyances, airplanes, space craft, flying machines, human-powered conveyances, and the like.

In various embodiments, the vehicle 100 may include different electronic components, for example, electronic control units for controlling different parts of the vehicle 100. These electronic components will generate heat during their operation and the heat may be discharged to prevent overheating the electronic components. With reference to FIG. 1, three exemplary positions 101, 102, 103 within the vehicle 100 for the electronic components can be provided. In some other instances, the vehicle 100 may have the electronic components located in any other positions on the vehicle 100. The locations of electronic components will vary from vehicle to vehicle depending on vehicle size and/or packaging.

In some embodiments, the cooling systems 200a, 200b, 200c that include a cooling plate in accordance with various embodiments disclosed herein may be arranged for cooling the corresponding electronic components at each of these positions: the cooling system 200a at the position 101, the cooling system 200b at the position 102, and the cooling system 200c at the position 103. In some other embodiments, the cooling system may be arranged for cooling all or a group of the electronic components, and the position of the cooling system would depend on vehicle size and/or packaging as described above. The above-mentioned cooling systems 200a, 200b, 200c each may incorporate a cooling plate 200 that may be made according to various embodiments as described in more detail with reference to FIGS. 2-9 below.

FIG. 2 shows a perspective view 300 of an assembled cooling plate 200 in accordance with embodiments of the present disclosure. The cooling plate 200 may be a liquid cooling plate that has a flow coolant to absorb heat from surfaces with high heat loads. In some embodiments, the coolant may be water. In some other embodiments, the coolant may be any suitable coolant that has the chemical and/or physical properties or characteristics to absorb heat and flow through the cooling plate 200.

As shown in FIG. 2, in some embodiments, the cooling plate 200 can be a sheet metal cooling plate that includes a top layer 21, a bottom layer 22, a fluid passage 23, an inlet fitting 27 and an outlet fitting 28. The top layer 21 and the bottom layer 22 each can be formed of a sheet metal. In some embodiments, the top layer 21 and the bottom layer 22 each can be made of a thin sheet metal layer, for example, a stamped sheet metal layer. In some other embodiments, one or both of the top layer 21 and the bottom layer 22 may be formed of a non-metal material.

The fluid passage 23 can be formed between the top layer 21 and the bottom layer 22 as a result of the assembly of the top layer 21 and the bottom layer 22. In the example of FIG. 2, the fluid passage 23 extends from one edge 24 of the cooling plate 200, in a shape of “U,” to the same edge 24 of the cooling plate 200. The fluid passage 23 has an inlet 25 on one edge 24 of the cooling plate 200, at one end of the “U” shape and an outlet 26 on the same edge 24 of the cooling plate 200, at the other end of the “U” shape. The inlet fitting 27 can be partially inserted into the inlet 25, and the outlet fitting 28 can be partially inserted into the outlet 26. In some other embodiments, the fluid passage 23 may have any other shape, for example, I-typed, or L-shaped, or serpentine, that extends from one edge of the cooling plate 200 to the same or another different edge of the cooling plate 200. The inlet 25 and the outlet 26 may be located on the same edge or on different edges, of the cooling plate 200.

In some other embodiments, there can be more than one inlet 25 and more than one outlet 26, wherein some of the inlets 25 and the outlets 26 may be arranged on the same edge of the cooling plate and spaced away from each other, and the remaining of the inlets 25 and the outlets 26 may be arranged on the different edges of the cooling plate 200.

A coolant, for example, water or other liquid coolant, may flow into the fluid passage 23 of the cooling plate 200 via the inlet 25 and the inlet fitting 27 from a coolant supply (not shown for simplicity). The coolant flows through the fluid passage 23 and then goes back into the coolant supply via the outlet 26 and the outlet fitting 28. Various electronics or other heat generating devices can interface to the top layer 21 or the bottom layer 22 to have the generated heat transferred into the coolant flowing in the cooling plate 200, and then the heat carried by the coolant ultimately goes out of the cooling plate 200.

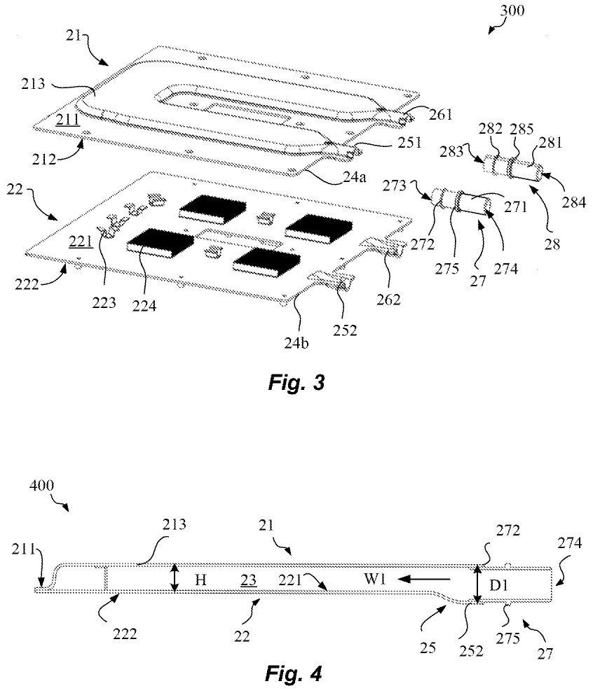

FIG. 3 shows an exploded view of the cooling plate shown in FIG. 2 in accordance with embodiments of the present disclosure. As shown in FIG. 3, in some embodiments, the top layer 21 has a top surface 211, a bottom surface 212 opposite to the top surface 211, and a raised portion 213. The bottom surface 212 can be substantially flat. The raised portion 213 can be formed for example by pressing the top layer 21 in a direction from the bottom surface 212 to the top surface 211 so that it protrudes above the top surface 211 and forms inside a fluid groove (not shown in FIG. 3 for simplicity). The fluid groove may have a semicircle or other arc-shaped cross section perpendicular to the flow direction in the fluid passage 23.

As shown in FIG. 3, the top layer 21 includes a top inlet wall 251 and a top outlet wall 261 on an edge 24a of the top layer 21. Both the top inlet wall 251 and the top outlet wall 261 extend outwardly from the edge 24a in a plane parallel with the top surface 211 or with the bottom surface 212. In some aspects, both the top inlet wall 251 and the top outlet wall 261 may extend outwardly from the edge 24a in a direction that can be substantially perpendicular to the edge 24a of the top layer 21. In some other aspects, the top inlet wall 251 and/or the top outlet wall 261 may extend outwardly from the edge 24a in a direction which can be not perpendicular to the edge 24a of the top layer 21.

As shown in FIG. 3, the bottom layer 22 has a top surface 221 and a bottom surface 222. In some embodiments, the bottom layer 22 can be flat. In other words, both the top surface 221 and the bottom surface 222 can be substantially flat. In the assembled state of the cooling plate 200, the top surface 221 of the bottom layer 22 can be in contact with and fluid-tightly fixed to the bottom surface 212 of the top layer 21. In the example of FIG. 3, on the top surface 221 of the bottom layer 22, four heat sinks 224 and several brackets 223 may be arranged on the flat bottom layer 22. In some embodiments, the heat sinks 224 extend from the top surface 221 of the bottom layer 22 into the fluid passage 23. In some other embodiments, there can be more or fewer than four heat sinks 224 provided on the top surface 221 of the bottom layer 22. In various aspects, one or more electronic components or any other surfaces with high heat loads (not shown for simplicity) may be in direct contact with the bottom surface 222 of the bottom layer 22. The flatness of the bottom layer 22 allows maximized contact area between those hot surfaces and the heatsinks arranged on the top surface 221 of the bottom layer 22, thereby ensuring the thermal performance of the cooling plate 200. In various aspects, the brackets 223 support the fluid passage 23 and enhance the strength of the cooling plate 200.

When the bottom layer 22 can be attached to the top layer 21, the fluid groove (not shown in FIG. 3 for simplicity) opens toward the bottom layer 22 and forms the fluid passage 23 between the top layer 21 and the bottom layer 22 as shown in FIG. 2. Due to the flat bottom layer 22 and the semicircle or other arc-shaped cross section of the fluid groove, the fluid passage 23 may have a cross section enclosed by an arc or a curved line and a straight line.

In some other embodiments of the present disclosure, the top layer 21 may be flat and the bottom layer 22 may have a raised portion forming inside the fluid groove, wherein the fluid groove forms the fluid passage 23 when the bottom layer 22 can be attached to the top layer 21.

By having one layer (top layer 21 or the bottom layer 22) to be flat and the fluid groove to be formed on the other layer (the bottom layer 22 or the top layer 21), the inlet fitting 27 can be substantially in line with a first direction along which the fluid passage extends from the inlet, and the outlet fitting 28 can be substantially in line with a second direction along which the fluid passage extends from the outlet. The overall fluid channel that includes the fluid passage 23 formed by the fluid groove and the inlet and outlet fitting can avoid elevation changes as the coolant can be flowing from the inlet fitting 27 to the outlet fitting 28. In this way, the coolant flow may have a flow geometry that can reduce the pressure drop of the coolant caused by flow resistance in the fluid passage 23, thereby maximizing the cooling efficiency of the cooling plate 200. Additionally, by having the inlet 25 and the outlet 26 on the edge of cooling plate 200 to receive and output the coolant, respectively, the height or thickness of the cooling plate 200 can be reduced. Because of the reduced height or thickness of the cooling plate 200, the packaging cost of the cooling plate and that of a cooling system that encloses the cooling plate may be lower, thereby saving on the total manufacturing cost of the cooling plate and the cooling system.

Further with reference to FIG. 3, the bottom layer 22 includes a bottom inlet wall 252 and a bottom outlet wall 262 on an edge 24b of the bottom layer 22. Both the bottom inlet wall 252 and the bottom outlet wall 262 extend outwardly from the edge 24b in a plane approximately parallel with the top surface 221 or with the bottom surface 222. In some aspects, both the bottom inlet wall 252 and the bottom outlet wall 262 may extend outwardly from the edge 24b in a direction that can be substantially perpendicular to the edge 24b of the bottom layer 22. In some other aspects, the bottom inlet wall 252 and/or the bottom outlet wall 262 may extend outwardly from the edge 24b in a direction which is not perpendicular to the edge 24b of the bottom layer 22.

With reference to FIG. 3, the edge 24a of the top layer 21 and the edge 24b of the bottom layer 22 may together form the edge 24 of the cooling plate 200 as shown in FIG. 2. The bottom inlet wall 252 matches and aligns with the top inlet wall 251 to form the inlet 25 and to enclose an opening (not shown in FIG. 3 for simplicity) of the inlet 25. The bottom outlet wall 262 matches and aligns with the top outlet wall 261 to form the outlet 26 and to enclose an opening (not shown in FIG. 3 for simplicity) of the outlet 26.

Although FIG. 2 and FIG. 3 show that the inlet 25 and the outlet 26 can be nearly perpendicular to the cooling plate 200, the inlet 25 and the outlet 26 can be positioned at any angle with respect to the plate, as long as they can be positioned in alignment with the flow direction of the coolant and without an elevation difference.

Further with reference to FIG. 3, in some embodiments, the inlet fitting 27 may have a tubular body 271 and a ring flange 272 surrounding the tubular body 271. The tubular body 271 has a first end 273 and a second opposite end 274. The first end 273 can be inserted into the opening of the inlet 25 so that the inlet fitting 27 may be in fluid communication with the inlet 25. The ring flange 272 can be positioned close to the first end 273 of the tubular body 271. In some embodiments, the ring flange 272 and the tubular body 271 may be an integral component. In some other embodiments, the ring flange 272 can be a separate component and it can be then fixed to the tubular body 271. When the inlet fitting 27 can be partially inserted within the inlet 25, the ring flange 272 abuts the top inlet wall 251 and the bottom inlet wall 252 of the inlet 25, respectively. In this way, the ring flange 272 may control the positioning of the inlet fitting 27 on the cooling plate 200 during assembly and seal over any gaps (not shown for simplicity) that may be present between the inlet fitting 27 and the inlet 25 once the inlet fitting 27 can be partially inserted into the inlet 25. In some other embodiments, a second ring flange 275 can be provided on the tubular body 271 and surrounding the tubular body 271. The second ring flange 275 can be close to the second end 274 and spaced apart from the ring flange 272. The second end 274 can be adaptable to be connected to a pipe structure, for example, a coolant delivery pipe not shown in FIG. 3 for simplicity. When the inlet fitting 27 can be connected to the pipe structure by inserting the second end 274 into the pipe structure, the second ring flange 275 can be not only attached to the pipe structure, but also may be used to position the inlet fitting 27 with regard to the pipe structure and control the length of the inlet fitting 27 extending in the pipe structure.

Further with reference to FIG. 3, in some embodiments, the outlet fitting 28 may have a tubular body 281 and a ring flange 282 surrounding the tubular body 281. The tubular body 281 has a first end 283 and a second opposite end 284. The first end 283 can be inserted into the opening of the outlet 26 so that the outlet fitting 28 may be in fluid communication with the outlet 26. The ring flange 282 can be positioned close to the first end 283 of the tubular body 281. In some embodiments, the ring flange 282 and the tubular body 281 may be an integral component. In some other embodiments, the ring flange 282 can be a separate component and it can be then fixed to the tubular body 281. When the outlet fitting 28 can be partially inserted within the outlet 26, the ring flange 282 abuts the top outlet wall 261 and the bottom outlet wall 262 of the outlet 26, respectively. In this way, the ring flange 282 may control the positioning of the outlet fitting 28 on the cooling plate 200 during assembly and seal over gaps (not shown for simplicity) that may be present between the outlet fitting 28 and the outlet 26 once the outlet fitting 28 can be partially inserted into the inlet 26. In some other embodiments, a second ring flange 285 can be provided on the tubular body 281 and surrounding the tubular body 281. The second ring flange 285 can be close to the second end 284 and spaced apart from the ring flange 282. The second end 284 can be adaptable to be connected to a pipe structure, for example, a coolant delivery pipe for shown in FIG. 3 for simplicity. When the outlet fitting 28 can be connected to the pipe structure by inserting the second end 284 into the pipe structure, the second ring flange 285 can be not only attached to the pipe structure, but also may be used to control the length of the inlet fitting 27 extending in the pipe structure.

FIG. 4 schematically shows a sectional view 400 of the cooling plate 200 taken along the line A-A of FIG. 2 excluding the brackets 223 and heat sinks 224 for simplicity, in accordance with embodiments of the present disclosure. As shown in FIG. 4, the inlet fitting 27 can be sandwiched between the top layer 21 and the bottom layer 22 and attached to both the top layer 21 and the bottom layer 22. In some embodiments, the inlet fitting 27 may be attached to the top layer 21 and to the bottom layer 22 by processing such as brazing and/or welding. In some other embodiments, the inlet fitting 27 may be attached to the top layer 21 and to the bottom layer 22 by processing such as press fit, glue/adhesive, diffusion bonding, and/or friction stir welding. The inlet fitting 27 can be substantially in line with a first direction W1 along which the fluid passage 23 extends from the inlet 25. Accordingly, a coolant may flow through the inlet 25, the inlet fitting 27, and the fluid passage 23 without elevation changes or bends and angles that may compromise flow geometry of the coolant flow. In this way, pressure drop of the coolant caused by flow resistance can be minimized, thereby maximizing the cooling efficiency of the cooling plate 200.

Further with reference to FIG. 4, the inlet 25 has a diameter D1 measured between the highest point of the top inlet wall 251 and the lowest point of the bottom inlet wall 252. The cooling plate 200 has a thickness H measured between the highest point of the raised portion 213 and the bottom surface 222 of the bottom layer 22. In some embodiments, the diameter D1 can be larger than the thickness H. With the larger diameter D1, the inlet fitting 27 may have a larger diameter, and accordingly the coolant may flow from the inlet fitting 27 into the inlet 25 and then into the cooling channel 23, with less pressure loss. As shown in FIG. 4, the inlet fitting 27 may extend in the same plane as the fluid passage 23 so that no elevation changes occur when the coolant flows from the inlet fitting 27 and enters into the fluid passage 23. This absence of elevation changes reduces the height or thickness of the cooling plate 200, thereby realizing a more compact packaging of a cooling system that includes the cooling plate 200.

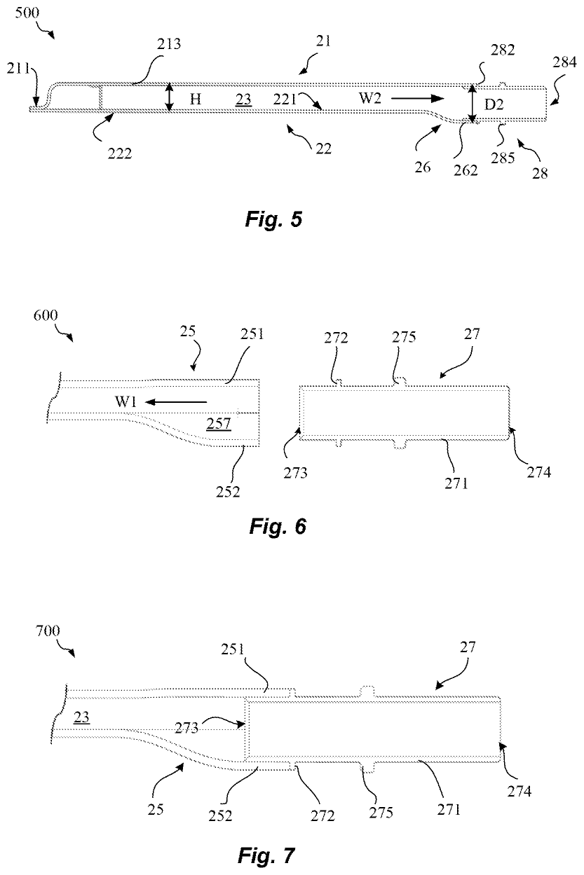

FIG. 5 schematically shows a sectional view 500 of the cooling plate 200 taken along the line B-B of FIG. 2 in accordance with embodiments of the present disclosure. As shown in FIG. 5, the outlet fitting 28 can be sandwiched between the top layer 21 and the bottom layer 22 and attached to both the top layer 21 and the bottom layer 22. In some embodiments, the outlet fitting 28 may be attached to the top layer 21 and to the bottom layer 22 by processing such as brazing and/or welding. In some other embodiments, the outlet fitting 28 may be attached to the top layer 21 and to the bottom layer 22 by processing such as press fit, glue/adhesive, diffusion bonding, and/or friction stir welding. The outlet fitting 28 can be substantially in line with a second direction W2 along which the fluid passage 23 extends towards the outlet 26. Accordingly, a coolant may flow through the fluid passage 23 and the outlet 26 and the outlet fitting 28 without elevation changes or bends and angles that may compromise flow geometry of the coolant flow. In this way, pressure drop of the coolant in the fluid channel caused by flow resistance can be minimized and thereby maximizing the cooling efficiency of the cooling plate 200. In some embodiments, the second direction W2 can be parallel with the first direction W1. In some other embodiments, the second direction W2 can be not parallel with the first direction W1.

Further with reference to FIG. 5, the outlet 26 has a diameter D2 measured between the highest point of the top outlet wall 261 and the lowest point of the bottom outlet wall 262. In some embodiments, the diameter D2 can be larger than the thickness H. With the larger diameter D2, the outlet fitting 28 may have a larger diameter, and accordingly the coolant may flow from the outlet 26 through the outlet fitting 28 to leave the fluid passage 23, with less pressure loss. Similar to the inlet fitting 27 as described above, the outlet fitting 28 may also extend in the same plane as the fluid passage 23 so that no elevation changes occur when the coolant flows from the fluid passage 23 to the outlet fitting 28. This absence of elevation changes reduces the height or thickness of the cooling plate 200, thereby realizing a more compact packaging of a cooling system that includes the cooling plate 200.

FIG. 6 is a sectional view 600 of the inlet and the inlet fitting of the example cooling plate 200 before the inlet fitting 27 and the inlet 25 can be assembled in accordance with embodiments of the present disclosure. As shown in FIG. 6, the inlet fitting 27 can be arranged in line with the inlet 25 and the first end 273 of the inlet fitting 27 can be adjacent to the inlet 25 before the first end 273 can be inserted into the opening 257 enclosed by the top inlet wall 251 and the bottom inlet wall 252. In some embodiments, the opening 257 has a substantially circular cross section perpendicular to the central line of the opening 257. In some other embodiment, the cross section of the opening 257 may have other shapes, as long as the cross section of the opening 257 matches the cross section of the inlet fitting 27. During the process of assembling, the first end 273 can be inserted into the opening 257 along the first direction W1 until the ring flange 272 abuts against the top inlet wall 251 and the bottom inlet wall 252. When the inlet fitting 27 can be assembled with the inlet 25, the first end 273 of the inlet fitting 27 can be inserted into the opening 257 of the inlet 25 and sandwiched by the top inlet wall 251 and the bottom inlet wall 252. Because the inlet 25 opens on an edge of the cooling plate 200, the inlet fitting 27 can be an on-edge fitting.

FIG. 7 shows a sectional view 700 of the inlet and the inlet fitting of the example cooling plate after the inlet 25 and the inlet fitting 27 can be assembled in according with embodiments of the present disclosure. As shown in FIG. 7, after the inlet fitting 27 can be assembled with the inlet 25, the ring flange 272 abuts against the top inlet wall 251 and the bottom inlet wall 252 and can be attached to the top inlet wall 251 and the bottom inlet wall 252, so that a fluid-tight connection between the inlet 25 and the inlet fitting 27 can be made.

The outlet fitting 28 may be assembled with the outlet 26 in a way similar to the inlet fitting 27 and a fluid-tight connection can also be made between the outlet 26 and the outlet fitting 28. Therefore, the detailed description of assembling the outlet fitting 28 can be omitted.

In various embodiments, the inlet and outlet fittings 27, 28 can be directly added on one or more edges of the cooling plate 200 in line with the directions along which the fluid passage 23 extends from the inlet 25 or the outlet 26 and can be sandwiched between the top layer 21 and the bottom layer 22. Various aspects of the subject matter disclosed herein allow the flow coolant to enter into the fluid passage 23 at the inlet 25 and leave the fluid passage 23 at outlet 26 without substantial change of flow direction that can be caused by bends of conventional liquid cooling plates in their cooling flow channels. The bends may exist when a fitting can be oriented perpendicular to a surface of the cooling plate or when the fitting can be mounted transverse to the surface of the cooling plate at an angle greater than 90 degrees. The bends may also exist when the fitting can be parallel to the surface of the cooling plate and has an elevation difference with regard to the surface of the cooling plate. These bends increase pressure drop in the cooling flow channels and reduce cooling efficiency. By adding the inlet and outlet fittings 27, 28 directly on one or more edges of the cooling plate 200, the inlet and outlet fittings 27, 28 of the present disclosure can be oriented to extend in the same plane as the fluid passage 23. Further, the inlet fitting 27 can be in line with the first direction W1 along which the fluid passage 23 extends from the inlet 25, and the outlet fitting 28 can be in line with the second direction W2 along which the fluid passage 23 extends towards the outlet 26. In this way, bends between the inlet fitting 27 and the fluid passage 23 and those between the outlet fitting 28 and the fluid passage 23 can be avoided, thereby providing a smoother flow transition into and out of the cooling plate 200. This resulted flow characteristics may lower pressure loss, and thereby increasing heat extraction from the electronic components, or any other surfaces with high heat loads.

To accommodate the fittings equipped with their inlets and outlets, conventional liquid cooling plates requires additional physical space and height above the cooling plate to allow the fittings and coolant supply lines to be mounted above the cooling plate. By moving the inlet and out fittings 27, 28 to be directly on one or more edges of the cooling plate 200 and to extend in the same plane as the fluid passage 23, a packaging benefit can also be provided due to the reduced height and a space occupied by the whole cooling plate 200, which provides more efficient system packaging. Meanwhile, by moving the inlet and outlet fittings 27, 28 to be directly on one or more edges of the cooling plate 200, the inlet 25, the outlet 26, the inlet fitting 27, and the outlet fitting 28 may all have a relatively large size but may not increase the height and space above the cooling plate 200.

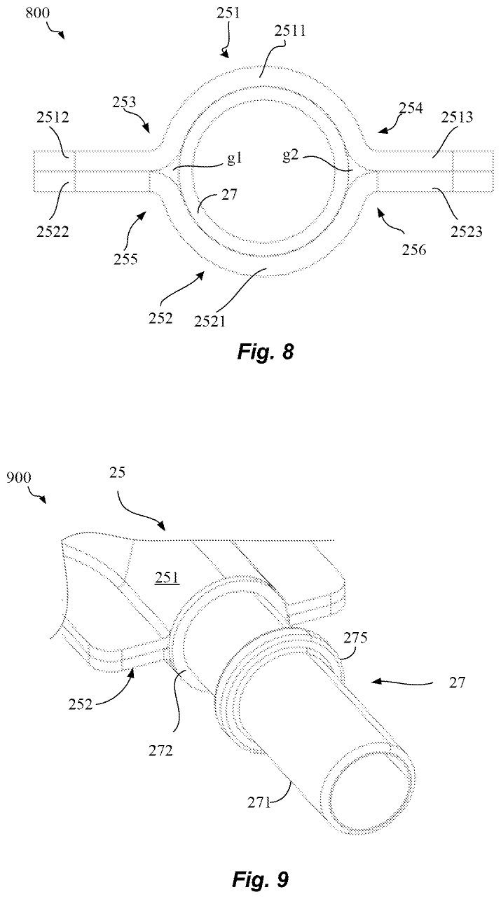

FIG. 8 shows a sectional view 800 of the inlet fitting 27 partially inserted within the inlet 25 of another example cooling plate in accordance with some embodiments of the present disclosure. The outlet fitting and the outlet may be made in the embodiments that can be identical or similar to the embodiments of the inlet fitting 27 and the inlet 25 as shown in FIG. 8. Therefore, any descriptions provided for the inlet fitting 27 and the inlet 25 should be understood to be equally applicable to the outlet fitting and the outlet. As shown in FIG. 8, the top inlet wall 251 may include a top curved wall portion 2511 and two top flat portions 2512, 2513. The first top flat portion 2512 extends outwardly from one side edge of the top curved wall portion 2511. A first top corner 253 can be formed between the first top flat portion 2512 and the top curved wall portion 2511. The second top flat portion 2513 extends outwardly from the other side edge of the top curved wall portion 2511, opposite to the first top flat portion 2512. A second top corner 254 can be formed between the second top flat portion 2513 and the top curved wall portion 2511.

As shown in FIG. 8, in some embodiments, the bottom inlet wall 252 may include a bottom curved wall portion 2521 and two bottom flat portions 2522, 2523. The first bottom flat portion 2522 extends outwardly from one side edge of the bottom curved wall portion 2521. A first bottom corner 255 can be formed between the first bottom flat portion 2522 and the bottom curved wall portion 2521. The second bottom flat portion 2523 extends outwardly from the other side edge of the bottom curved wall portion 2521, opposite to the first bottom flat portion 2522. A second bottom corner 256 can be formed between the second bottom flat portion 2523 and the bottom curved wall portion 2521.

As shown in FIG. 8, the first top flat portion 2512 of the top inlet wall 251 can be aligned with and fluid-tightly attached to the first bottom flat portion 2522 of the bottom inlet wall 252. The second top flat portion 2513 of the top inlet wall 251 can be aligned with and fluid-tightly attached to the second bottom flat portion 2523 of the bottom inlet wall 252.

The top outlet wall 261 can be substantially identical to the top inlet wall 251, and the bottom outlet wall 262 can be substantially identical to the bottom inlet wall 252. Accordingly, the detailed description of both the top outlet wall 261 and the bottom outlet wall 262 can be omitted. In some embodiments, the opening of the outlet 26 has a substantially circular cross section perpendicular to the central line of the opening. The outlet fitting 28 can be partially inserted into the opening enclosed by the top outlet wall 261 and the bottom outlet wall 262. The outlet fitting 28 can also be sandwiched between the top outlet wall 261 and the bottom outlet wall 262. Because the outlet 26 opens on an edge of the cooling plate 200, the outlet fitting 28 can be an on-edge fitting.

For the example of FIG. 8, the cooling plate 200 may not have a ring flange on the inlet fitting 27. A first gap g1 may be present between the first top corner 253, the first bottom corner 255 and the inlet fitting 27, and a second gap g2 may be present between the second top corner 254, the second bottom corner 256 and the inlet fitting 27. Similarly, there may be gaps at the interfaces between the outlet 26 and the outlet fitting 28. The first gap g1 and the second gap g2 may be formed as a result of joining the top layer 21 and the bottom layer 22 and thereby joining the top inlet wall 251 and the bottom inlet wall 252. In some aspects, the top and bottom layers 21 and 22 (including the top inlet wall and the bottom inlet wall 251 and 252) may be joined by brazing and/or soldering processes. In some other aspects, the joining may be made by other suitable processing with the purpose of creating a reliable and tight connection between metals. In some embodiments, the top and bottom layers 21 and 22 (including the top inlet wall and the bottom inlet wall 251 and 252) may be further compressed or squeezed by a mechanical processing method such as crimping to reduce the formed gaps g1 and g2, as described in details below.

FIG. 9 shows a perspective view 900 of the inlet area of an example cooling plate with a ring flange in accordance with embodiments of the present disclosure. The outlet fitting and the outlet may be made in the embodiments that can be identical or similar to the embodiments of the inlet fitting 27 and the inlet 25 as shown in FIG. 9. Therefore, any descriptions provided for the inlet fitting 27 and the inlet 25 should be understood to be equally applicable to the outlet fitting and the outlet. As shown in FIG. 9, the ring flange 272 of the inlet fitting 27 can be attached to the top inlet wall 251 and the bottom inlet wall 252 that can be blocked in this view, respectively, for example by processing such as a brazing process, a welding process, a press fit, glue/adhesive, diffusion bonding, and/or friction stir welding. By attaching the inlet fitting 27 with the ring flange 272 to the top layer 21 and the bottom layer 22, the fluid leakage that can be potentially caused by the first and second gaps g1, g2 as shown in FIG. 8 may be avoided or reduced by increasing the attaching area between the inlet fitting 27 and the top and bottom layers 21, 22. The ring flange 272 extends radially and away from the outside circumferential surface of the inlet fitting 27 and has a radial thickness. This radial thickness of the ring flange 272 causes it to protrude from the surface of the tubular body 271 of the inlet fitting 27 and thereby blocks melted brazing or welding materials from flowing from the first end 273 over the ring flange 272 to the remaining circumferential surface of the inlet fitting 27 during the assembling process. In this way, the remaining circumferential surface of the inlet fitting 27 can be clean by limiting the melted brazing or welding materials on the area between the first end 273 and the ring flange 272.

In some other embodiments, in order to increase the fluid-tightness between the inlet 25 and the inlet fitting 27, a braze washer (not shown in the drawings for simplicity) can be provided between the ring flange 272 and the top and bottom layers 21, 22. During the assembly of the top and bottom layers 21 and 22, a brazing process and/or a welding process may be used, the braze washer may melt and fill up gaps g1, g2, and firmly bonds the inlet fitting 27 and the top and bottom layers 21 and 22 upon solidification, thereby enhancing the fluid-tightness between the inlet fitting 27 and the inlet 25. The alloy of braze washer may be chosen from copper based brazing filler alloys or silver based brazing filler alloys.

In some embodiments, a braze washer can also be positioned between the ring flange 282 of the outlet fitting 28 and the top and bottom layers 21, 22. During the brazing process or the welding process, the braze washer may be melted, and the alloy of the braze washer may fill or reduce gaps between the outlet fitting 28 and the top and bottom layers 21, 22 so that the strength of connection between the outlet fitting 28 and the top and bottom layers 21, 22 can be enhanced for the fluid-tightness between the outlet fitting 28 and the outlet 26.

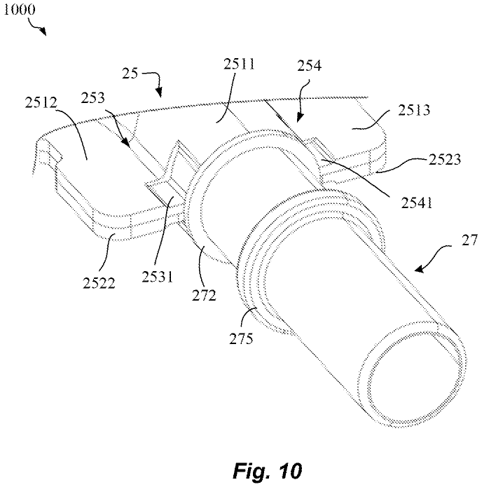

FIG. 10 shows a perspective view 1000 of an inlet area of another example cooling plate as a result of a crimping process in accordance with various embodiments of the present disclosure. The outlet fitting and the outlet may be made in the embodiments that can be identical or similar to the embodiments of the inlet fitting 27 and the inlet 25 as shown in FIG. 10. Therefore, any descriptions provided for the inlet fitting 27 and the inlet 25 should be understood to be equally applicable to the outlet fitting and the outlet. With reference to FIG. 10, the cooling plate also has the ring flange 272 on the inlet fitting 27. A first top crimped region 2531 may be formed at the first top corner 253, and a second top crimped region 2541 may be formed at the second top corner 254. Both the first and second top crimped regions 2531, 2541 may be formed by crimping with a preset depth the outside surface of the top inlet wall 251 at the first and second top corner 253, 254, respectively, as shown in FIG. 8. Similarly, bottom crimped regions may be formed at the first and second bottom corners 255, 256, respectively, as shown in FIG. 8. These crimped regions each have the same width, length, and depth. After the inlet 25 can be crimped at its four corners, both the first and second gaps g1, g2 may be reduced to the size which can be industrially acceptable for a fluid-tight cooling plate. The crimped regions reduce the gaps so that any extra material from the brazing or welding process may flow into the gaps and adequately fill the interfaces between the inlet 25 and the inlet fitting 27. The combination of the crimped regions of the inlet 25 and the ring flange 272 of the inlet fitting 27 may further enhance the fluid-tightness between the inlet 25 and the inlet fitting 27, thereby ensuring a fluid-tight cooling plate 200.

In some embodiments, all the four crimped regions of the inlet 25 may be formed simultaneously. In other embodiments, top crimped regions of the inlet 25 may be formed first and then the two bottom crimped regions of the inlet 25 may be formed. In some other embodiments, only one crimped region may be formed by each crimping.

In some embodiments, the four corners of the outlet 26 may be crimped to form a corresponding crimped region at each of the four corners, in order to reduce gaps between the outlet 26 and the outlet fitting 28. The crimped regions of the outlet 26 can be configured similar to the crimped regions of the inlet 25. Therefore, the detailed description of these crimped regions can be omitted. The combination of the crimped regions of the outlet 26 and the ring flange 282 of the outlet fitting 28 may further enhance the fluid-tightness between the outlet 26 and the outlet fitting 28.

The cooling plate 200 according to the present disclosure may be produced in the following exemplary way. In this example, the cooling plate 200 includes the top layer 21, the bottom layer 22, the heat sinks 224, the brackets 223, the inlet fitting 27 with the ring flange 272, and the outlet fitting 28 with the ring flange 282. In some embodiments, a braze washer may be provided between the inlet 25 and the inlet fitting 27 and between the outlet 26 and the outlet fitting 28. Each of the top layer 21 and the bottom layer 22 can be made of a thin sheet metal layer. The top layer 21, the bottom layer 22, the heat sinks 224, the brackets 223, the inlet fitting 27, and the outlet fitting 28 can be all first preassembled in a fixture. The heat sinks 224 and brackets 223 may be temporarily held in position, for example, by a laser welding or other mechanical methods. Then, the entire assembly can be brazed or welded in an oven or any other suitable industrial devices at one time to form a fluid-tight unit. During the brazing or welding process, the braze washer can melt and fill in any gaps between the fittings and the inlet or the outlet to further reduce the gaps.

The cooling plate 200 according to the present disclosure may be produced in another exemplary way. In this example, the cooling plate 200 comprises the top layer 21, the bottom layer 22, the heat sinks 224, the brackets 223, the inlet fitting 27 with the ring flange 272, and the outlet fitting 28 with the ring flange 282. In some embodiments, a braze washer may be provided between the inlet 25 and the inlet fitting 27 and between the outlet 26 and the outlet fitting 28. Each of the top layer 21 and the bottom layer 22 can be made of a thin sheet metal layer. The assembling way for the cooling plate 200 can be identical to the above exemplary way except for the following difference. After the top layer 21, the bottom layer 22, the heat sinks 224, the brackets 223, the inlet fitting 27, and the outlet fitting 28 can be preassembled, the inlet 25 and the outlet 26 each can be crimped at their four corners. The crimped regions may be made at the same time or separately. After the crimped regions can be formed, the entire assembly can be brazed or welded in an oven or any other suitable industrial devices at one time to form a fluid-tight unit.

The cooling plate 200 according to the present disclosure may be produced in another exemplary way. In this example, the cooling plate 200 includes the top layer 21, the bottom layer 22, the heat sinks 224, the brackets 223, the inlet fitting 27 without the ring flange 272, and the outlet fitting 28 without the ring flange 282. Each of the top layer 21 and the bottom layer 22 can be made of a thin sheet metal layer. The top layer 21, the bottom layer 22, the heat sinks 224, the brackets 223, the inlet fitting 27, and the outlet fitting 28 may be preassembled together, for example, preassembled in a fixture. Then the top layer 21, the bottom layer 22, the inlet fitting 27, and the outlet fitting 28 can be brazed or soldered to form an assembly by a primary brazing or welding process into a single piece. After this primary brazing or welding process, the assembly may be further treated by a secondary flame brazing process with a temperature lower than the temperature of the primary process, between the inlet 25 and its inlet fitting 27 and between the outlet 26 and its outlet fitting 28. A lower temperature alloy may be manually added to interfaces between the inlet and its inlet fitting and between the outlet and its outlet fitting. The lower temperature alloy may be chosen from copper based brazing filler alloys or silver based brazing filler alloys, for example, AWS BAg-20 or AWS BAg-35. By the flame brazing process, any holes not filled by the primary brazing step can be fully filled by the lower temperature alloy.

While particular embodiments have been described, alternatives, modifications, variations, improvements, and substantial equivalents that are or may be presently unforeseen may arise to applicants or skilled in the art. Accordingly, the appended claims as filed and as they may be amended, are intended to embrace all such alternatives, modifications variations, improvements, and substantial equivalents.

What is claimed is:

1. A cooling plate comprising:
a top layer;
a bottom layer attached to the top layer;
a fluid passage formed between the top layer and the bottom layer and having an inlet and an outlet, wherein the inlet forms on a first edge of the cooling plate and the outlet forms on a second edge of the cooling plate, and wherein one of the top layer and the bottom layer is flat and the other of the top layer and the bottom layer has a raised portion forming inside a fluid groove, and the fluid groove opens to the one of the top layer and the bottom layer and forms the fluid passage;
an inlet fitting being partially inserted into the inlet, wherein the inlet fitting is sandwiched between the top layer and the bottom layer and extends substantially in the same plane as the fluid passage; and
an outlet fitting being partially inserted into the outlet, wherein the outlet fitting is sandwiched between the top layer and the bottom layer and extends substantially in the same plane as the fluid passage.

2. The cooling plate of claim 1, wherein the inlet fitting is substantially in line with a first direction along which the fluid passage extends from the inlet, and the outlet fitting is substantially in line with a second direction along which the fluid passage extends from the outlet.

3. The cooling plate of claim 1, wherein the inlet and the outlet each includes a top wall formed on the top layer and a bottom wall formed on the bottom layer, the top wall and the bottom wall of the inlet and the outlet extending outwardly from the first and second edge of the cooling plate respectively and enclosing an opening for receiving the inlet fitting or the outlet fitting.

4. The cooling plate of claim 3, wherein the top wall has a first top corner and a second top corner formed at opposite sides of the top wall, respectively, and the bottom wall has a first bottom corner and a second bottom corner formed at opposite sides of the bottom wall, respectively.

5. The cooling plate of claim 1, wherein the inlet fitting and the outlet fitting are parallel with each other.

6. The cooling plate of claim 1, wherein the top layer and the bottom player each are made of a sheet metal layer.

7. The cooling plate of claim 1, further comprising a ring flange fitted around the inlet fitting and attached to both the top layer and the bottom layer.

8. The cooling plate of claim 7, further comprising an alloy at least partially filled between the inlet fitting and the inlet.

9. The cooling plate of claim 1, further comprising a ring flange fitted around the outlet fitting and attached to both the top layer and the bottom layer.

10. The cooling plate of claim 9, further comprising an alloy at least partially filled between the outlet fitting and the outlet.

11. The cooling plate of claim 1, wherein a diameter of each of the inlet and outlet is larger than a thickness of the cooling plate at a location through which the fluid passage extends.

12. The cooling plate of claim 1, wherein the first edge and the second edge are the same edge of the cooling plate and the inlet and the outlet are spaced away from each other on the same edge of the cooling plate.

13. The cooling plate of claim 1, wherein the first edge of the cooling plate is different from the second edge of the cooling plate.

14. The cooling plate of claim 1, wherein the cooling plate includes more than one inlet and more than one outlet.

15. The cooling plate of claim 1, further comprising a bracket disposed between the top layer and the bottom layer.

16. A cooling system comprising a cooling plate, wherein the cooling plate comprises:
a top layer;
a bottom layer attached to the top layer;
a fluid passage formed between the top layer and the bottom layer and having an inlet and an outlet, wherein the inlet forms on a first edge of the cooling plate and the outlet forms on a second edge of the cooling plate, and wherein one of the top layer and the bottom layer is flat and the other of the top layer and the bottom layer has a raised portion forming inside a fluid groove, and the fluid groove opens to the one of the top layer and the bottom layer and forms the fluid passage;
an inlet fitting being partially inserted into the inlet, wherein the inlet fitting sandwiched between the top layer and the bottom layer and extends substantially in the same plane as the fluid passage; and
an outlet fitting being partially inserted into the outlet, wherein the outlet fitting sandwiched between the top layer and the bottom layer and extends substantially in the same plane as the fluid passage.

17. The cooling system of claim 16, wherein the cooling system is used in a vehicle.

18. The cooling system of claim 16, wherein the inlet fitting is substantially in line with a first direction along which the fluid passage extends from the inlet, and the outlet fitting is substantially in line with a second direction along which the fluid passage extends from the outlet.

19. The cooling system of claim 16, wherein the first edge and the second edge are the same edge of the cooling plate and the inlet and the outlet are spaced away from each other on the same edge of the cooling plate.

20. The cooling system of claim 16, wherein the top layer and the bottom player each are made of a sheet metal layer.
